(19) United States
(12) Patent Application Publication
(10) Pub. No.: US 2015/0136464 A1
(43) Pub. Date: May 21, 2015

(54) Electronic Device

(71) Applicant: Kabushiki Kaisha Toshiba, Tokyo (JP)

(72) Inventors: Akihisa Shimizu, Tokyo (JP); Takahiro Sakaguchi, Ome-shi (JP)

(21) Appl. No.: 14/335,753

(22) Filed: Jul. 18, 2014

(30) Foreign Application Priority Data
Nov. 18, 2013 (JP) 2013-237754

(51) Int. Cl. H05K 1/18; H01G 2/06; H05K 1/11

(52) U.S. Cl. CPC H05K 1/181; H05K 1/111; H01G 2/065; H05K 2201/10015
USPC 174/260

(57) ABSTRACT

According to one embodiment, an electronic device includes a printed circuit board on which mounted is a multilayer ceramic capacitor includes a rectangular parallelepiped capacitor main body in which a pair of external electrodes are formed on both ends in a shorter side. The electronic device has a mount structure in which portions of the pair of external electrodes are soldered to the printed circuit board while setting a width of first and second pads provided respectively on the pair of external electrodes less than a width of the pair of external electrodes.

### CROSS-REFERENCE TO RELATED APPLICATIONS

This application is based upon and claims the benefit of priority from Japanese Patent Application No. 2013-237754, filed Nov. 18, 2013, the entire contents of which are incorporated herein by reference.

### FIELD

Embodiments described herein relate generally to electronic devices in which a multilayer ceramic capacitor is mounted on a printed circuit board.

### BACKGROUND

A great number of electronic components are contained at a high packing density on a printed circuit board used for small-sized electronic devices, for example, personal computers (PCs), tablet computers and mobile phones. One of these electronic components is a multilayer ceramic capacitor.

The multilayer ceramic capacitor is a chip-type ceramic capacitor in which a great number of dielectric materials and electrodes are stacked one on another. Owing to the excellent high-frequency characteristics of ceramics, a large capacitance can be realized with a small-size capacitor. However, when an alternating voltage is applied to the multilayer ceramic capacitor, electrostrictive strain occurs in the ceramic which forms the dielectric material. Due to this phenomenon, the printed circuit board vibrates, which is heard by the user as a singing noise.

In order to prevent the singing noise of the board produced as a result of to the electrostrictive strain, there is a component mounting method in which, for example, a metallic support member is provided on an electrode of a capacitor to mount the capacitor such that it floats above the printed circuit board. Further, there is also a method in which an electrode is formed on a lateral side (long side) of the main body in the internal structure of the capacitor itself.

With the method of providing a support member for the capacitor, however, specialized components therefor are required, which accordingly increase the production cost. On the other hand, with the method of modifying the internal structure of the capacitor itself, the capacitor needs to be subjected to a specialized process.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is a sectional view showing a mount structure of a multilayer ceramic capacitor provided in an electronic device according to an embodiment;

FIG. 2 is a perspective view showing an appearance of a general multilayer ceramic capacitor according to the embodiment;

FIG. 3A is a top view showing a structure of a first external electrode of the general multilayer ceramic capacitor according to the embodiment;

FIG. 3B is a top view showing a structure of a second external electrode of the general multilayer ceramic capacitor according to the embodiment;

FIG. 4 is a perspective view showing an appearance of an LW-reverse-type multilayer ceramic capacitor according to the embodiment;

FIG. 5A is a top view showing a structure of a first external electrode of the LW-reverse-type multilayer ceramic capacitor according to the embodiment;

FIG. 5B is a top view showing a structure of a second external electrode of the LW-reverse-type multilayer ceramic capacitor according to the embodiment;

FIG. 6 is an explanatory view showing a mount structure the LW-reverse-type multilayer ceramic capacitor according to the embodiment;

FIG. 7 is a perspective view showing the LW-reverse-type multilayer ceramic capacitor according to the embodiment, being soldered;

FIG. 8 is a lateral view showing the LW-reverse-type multilayer ceramic capacitor according to the embodiment, being soldered;

FIG. 9 is a diagram showing a displacement of the circuit board of the general multilayer ceramic capacitor according to the embodiment;

FIG. 10 is a diagram showing a displacement of the circuit board (pad width) of the LW-reverse-type multilayer ceramic capacitor according to the embodiment;

FIG. 11 is a view showing an example of the case where a pad is provided at a position deviated from the central portion to one end in an external electrode of an LW-reverse-type multilayer ceramic capacitor according to another embodiment;

FIG. 12 is a view showing another example of the case where pads are provided at positions diagonal to each other on the respective external electrodes of the LW-reverse-type multilayer ceramic capacitor according to the another embodiment; and

FIG. 13 is a view showing still another example of the case where a plurality of pads are provided on an external electrode of the LW-reverse-type multilayer ceramic capacitor according to the another embodiment.

### DETAILED DESCRIPTION

Various embodiments will be described hereinafter with reference to the accompanying drawings.

In general, according to one embodiment, an electronic device includes a printed circuit board on which mounted is a multilayer ceramic capacitor including a rectangular parallelepiped capacitor main body in which a pair of external electrodes are formed on both ends in a shorter side. The electronic device has a mount structure in which portions of the pair of external electrodes are soldered to the printed circuit board while setting a width of first and second pads provided respectively on the pair of external electrodes shorter than a width of the pair of external electrodes.

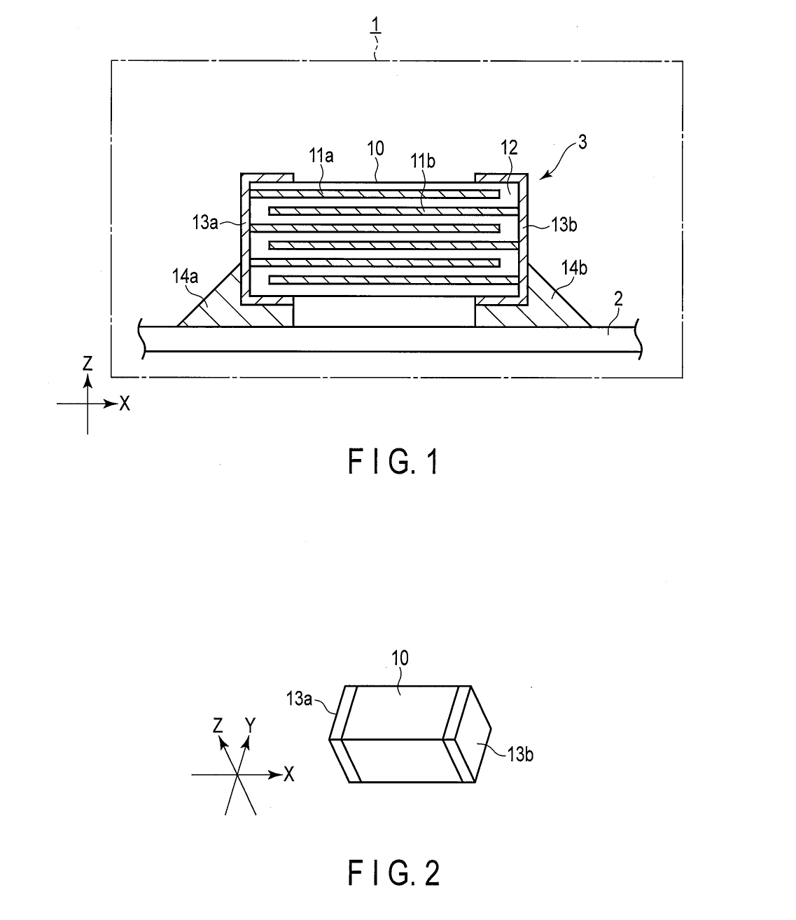

FIG. 1 is a sectional view showing a mount structure of a multilayer ceramic capacitor provided in an electronic device according to an embodiment. Note that the example shown in FIG. 1 is a general two-terminal multilayer ceramic capacitor.

A multilayer ceramic capacitor 3, which is an electronic component, is mounted on a printed circuit board 2 of an electronic device 1. Note that the electronic device 1 may be, for example, a PC, tablet computer or mobile phone.

The multilayer ceramic capacitor 3 includes a rectangular parallelepiped capacitor main body 10, pairs of internal electrodes 11a and 11b formed inside the capacitor main body 10 and a pair of external electrodes 13a, 13b formed on an outer surface of the capacitor main body 10.

The pairs of internal electrodes 11a and 11b are multilayered alternately inside the capacitor main body 10 while interposing a dielectric layer 12 between each pair. Further, the internal electrodes 11a and 11b are connected alternately to the external electrodes 13a and 13b, respectively. The external electrodes 13a and 13b are formed on the outer surfaces of the capacitor main body 10 such as to face each other.

The multilayer ceramic capacitor 3 is mounted on the printed circuit board 15 at predetermined positions by means of solder members 14a and 14b. More specifically, the solder members 14a and 14b (in paste) are printed at the bonding sections on the printed circuit board 15. Then, the multilayer ceramic capacitor 3 is mounted thereon, and the solder members 14a and 14b are fused with infrared radiation or the like, for bonding.

Here, in the multilayer ceramic capacitor 3 having the above-described structure, when a voltage is applied to the internal electrodes 11a and 11b in a laminating direction, the capacitor main body 10 expands in the laminating direction, and it shrinks in a direction perpendicular to the laminating direction. On the other hand, when the polarity of the voltage is reversed, the multilayer ceramic capacitor 3 shrinks in the laminating direction, and expands in a direction perpendicular to the laminating direction. This phenomenon is called electrostrictive strain. When the capacitor main body 10 expands and shrinks because of electrostrictive strain, the printed circuit board 2 vibrates in short cycles, which creates a singing noise when heard by the user.

In order to prevent the vibration of the printed circuit board 2 due to the electrostrictive strain occurring in the multilayer ceramic capacitor 3, the following countermeasures may be taken.

As the multilayer ceramic capacitor 3, an LW-reverse-type multilayer ceramic capacitor should be employed.

The width of each pad is set smaller than the width of an electrode (external electrode) of the capacitor. Note that by “pad” is meant a bonding section on a printed circuit board, and it may be called a land in some cases.

Here, the difference between the general multilayer ceramic capacitor and the LW-reverse-type multilayer ceramic capacitor will now be described.

(General multilayer ceramic capacitor)

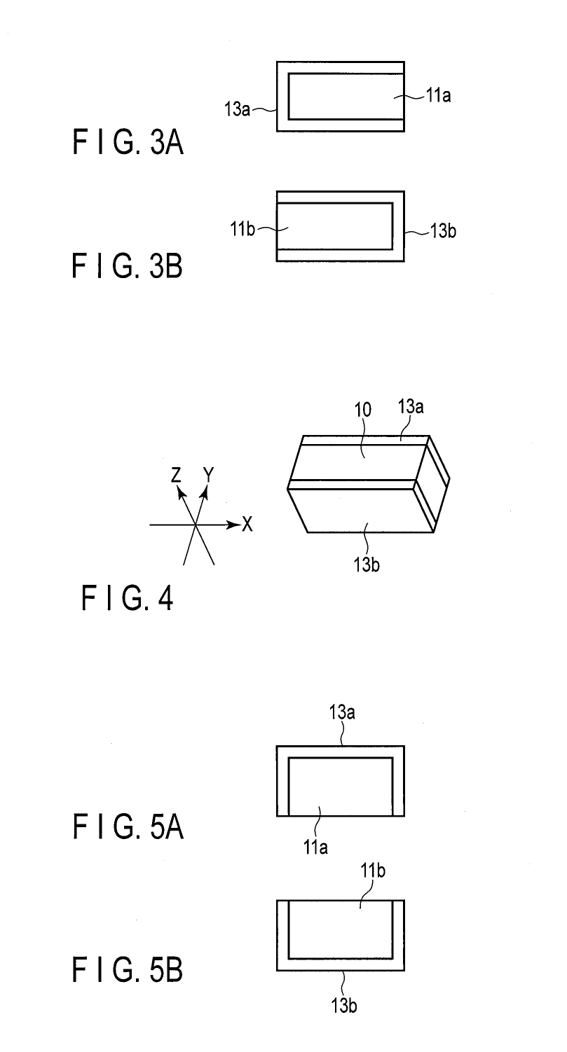

FIG. 2 is a perspective view showing an appearance of a general multilayer ceramic capacitor. FIG. 3A shows a structure of a first external electrode of the general multilayer ceramic capacitor when viewed from top, whereas FIG. 3B shows a structure of a second external electrode of the general multilayer ceramic capacitor when viewed from top.

As shown in FIG. 2, in the general multilayer ceramic capacitor, a pair of external electrodes 13a and 13b are formed such as to face each other on both long-side ends (in the X-direction) of a rectangular parallelepiped capacitor main body 10. In other words, the general multilayer ceramic capacitor has a structure in which the external electrodes 13a and 13b are formed on shorter sides of the capacitor main body 10

As shown in FIGS. 3A and 3B, of the internal electrodes 11a and 11b multilayered in the capacitor main body 10, the first internal electrodes 11a are drwan out to one end of the capacitor main body 10 to be connected to the external electrode 13a. On the other hand, the second internal electrodes 11b are drwan out to the other end of the capacitor main body 10 to be connected to the external electrode 13b.

(LW-reverse-type multilayer ceramic capacitor)

FIG. 4 is a perspective view showing an appearance of an LW-reverse-type multilayer ceramic capacitor. FIG. 5A shows a structure of a first external electrode of the LW-reverse-type multilayer ceramic capacitor when viewed from top. FIG. 5B shows a structure of a second external electrode of the LW-reverse-type multilayer ceramic capacitor when viewed from top.

As can be seen from FIG. 4, the LW-reverse-type multilayer ceramic capacitor is different from the general multilayer ceramic capacitor in the positions of the external electrodes 13a and 13b. That is, in the LW-reverse-type multilayer ceramic capacitor, a pair of external electrodes 13a and 13b are formed such as to face each other on both short-side ends (in the Y-direction) of a rectangular parallelepiped capacitor main body 10. In other words, the LW-reverse-type multilayer ceramic capacitor has a structure in which the external electrodes 13a and 13b are formed on long sides of the capacitor main body 10.

As shown in FIGS. 5A and 5B, of the internal electrodes 11a and 11b multilayered in the capacitor main body 10, the first internal electrodes 11a are drwan out to one end of the capacitor main body 10 to be connected to the external electrode 13a. On the other hand, the second internal electrodes 11b are drwan out to the other end of the capacitor main body 10 to be connected to the external electrode 13b.

Here, the amount of displacement of the main body 10, caused by the electrostrictive strain is larger in the X-direction indicated in FIG. 1, that is, the longitudinal direction of the main body 10, as compared to that of the Y-direction or Z-direction. With this structure, when the external electrodes 13a and 13b formed on the long-side ends of the capacitor main body 10 are bonded to the printed circuit board 2, the printed circuit board 2 is shaken together with the main body 10, which makes it likely to generate singing noise.

In order to suppress the above-described circuit board vibrations, let us consider to decrease the distance between bond sections of the circuit board using an LW-reverse-type multilayer ceramic capacitor.

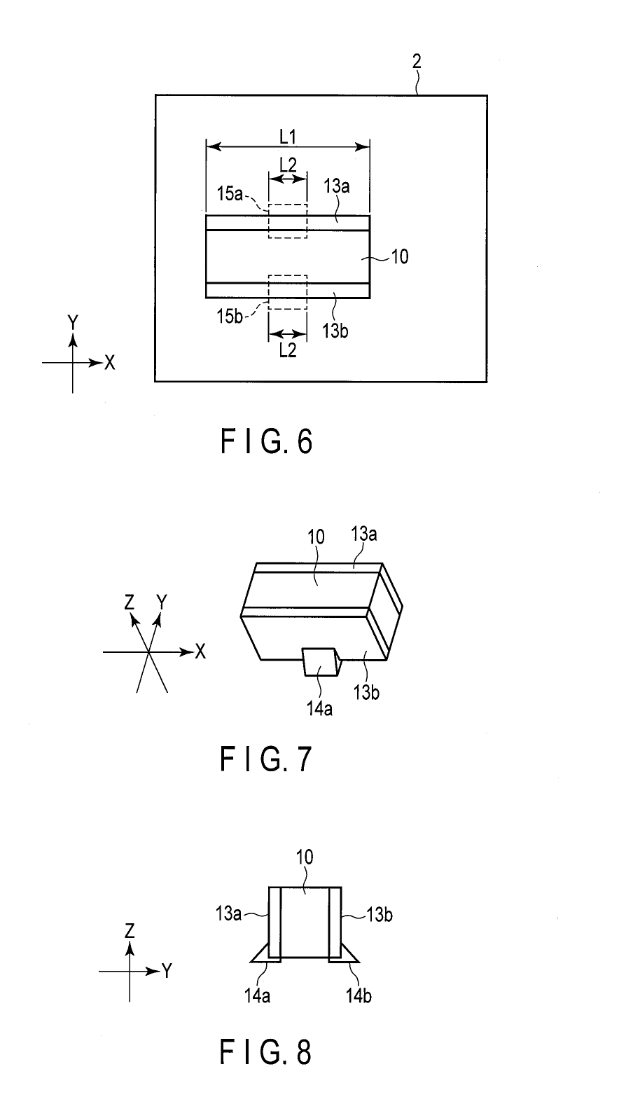

FIG. 6 is an explanatory view showing a mount structure the LW-reverse-type multilayer ceramic capacitor.

In the LW-reverse-type multilayer ceramic capacitor, the external electrodes 13a and 13b are formed on both short-side ends (Y-direction) of the capacitor main body 10. With this structure, the width of each electrode is larger than that of the general multilayer ceramic capacitor.

As shown in FIG. 6, the width L2 of pads 15a and 15b for bonding to the electrodes formed on the printed circuit board 15 is set to be less than width L1 of the external electrodes 13a and 13b. The first pad 15a corresponds to the first external electrode 13a, whereas the second pad 15b corresponds to the second external electrode 13b. The width L2 of the pads 15a and 15b is set to be less than the width L1 of the external electrodes 13a and 13b so that both long-side ends of the main body 10, which exhibits a large amount of displacement, do not bond to the printed circuit board 15.

Further, the pads 15a and 15b are set near the centers of the external electrodes 13a and 13b, respectively. With this structure, when the capacitor is soldered at the positions of the pads 15a and 15b, it can be bonded horizontally without floating one end of the main body 10.

FIG. 7 is a perspective view showing the LW-reverse-type multilayer ceramic capacitor being soldered, and FIG. 8 is a lateral view showing the LW-reverse-type multilayer ceramic capacitor being soldered.

With the width of the pads 15a and 15b being set to be less than that of the external electrodes 13a and 13b, the solder members 14a and 14b are attached to only portions of the external electrodes 13a and 13b, respectively. In this example, the locations of the pads 15a and 15b are near the centers of the external electrodes 13a and 13b, respectively. Accordingly, the solder members 14a and 14b are attached near the centers of the external electrodes 13a and 13b, respectively.

As described above, an LW-reverse-type multilayer ceramic capacitor including external electrodes 13a and 13b in a short-side direction (Y-direction) of the capacitor main body 10, is employed here, and the external electrodes 13a and 13b are soldered by their portions to the printed circuit board 2. With this structure, the vibration of the main body 10 can be reduced as compared to the general structure of the ceramic capacitor, thereby making it possible to prevent the production of singing noise.

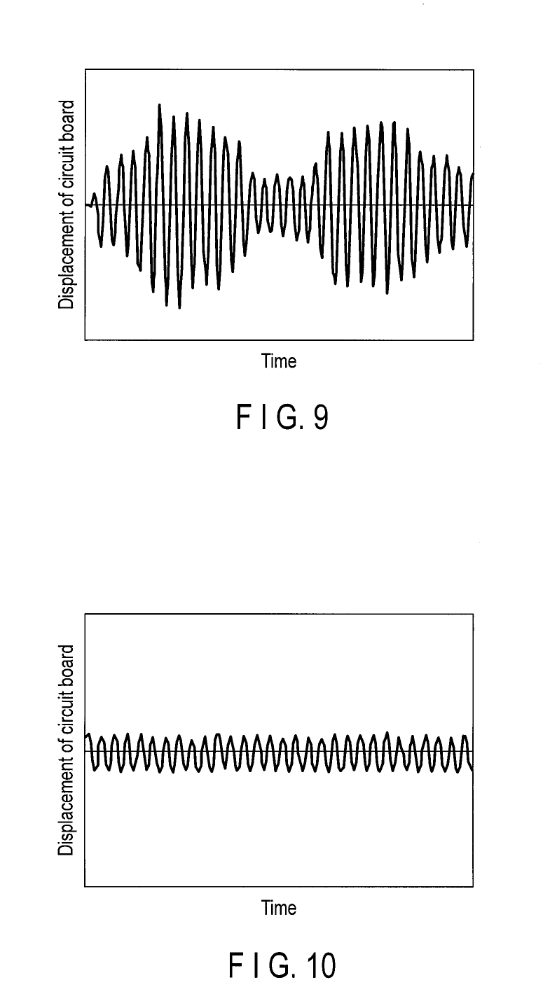

How the singing noise can be prevented is illustrated in FIGS. 9 and 10.

FIG. 9 shows the displacement of the circuit board of the general multilayer ceramic capacitor, whereas FIG. 10 shows the displacement of the circuit board (pad width) of the LW-reverse-type multilayer ceramic capacitor.

In the general multilayer ceramic capacitor, the printed circuit board 2 greatly vibrates as the capacitor main body 10 expands and contracts repeatedly, which makes it likely to produce the singing noise. By contrast, with the structure of the LW-reverse-type multilayer ceramic capacitor, in which the printed circuit board 2 is mounted by a narrower width of the pads, the vibration caused by the repeated expansions and contractions does not easily propagate to the capacitor main body 10. In this manner, the printed circuit board 2 deforms less, and therefore the singing noise is not produced.

(Other Embodiments)

In the above-described embodiment, the pads 15a and 15b are provided near the centers of the external electrodes 13a and 13b, respectively, in the LW-reverse-type multilayer ceramic capacitor (FIG. 6). But, the pads 15a and 15b are not necessarily located near the centers of the external electrodes 13a and 13b.

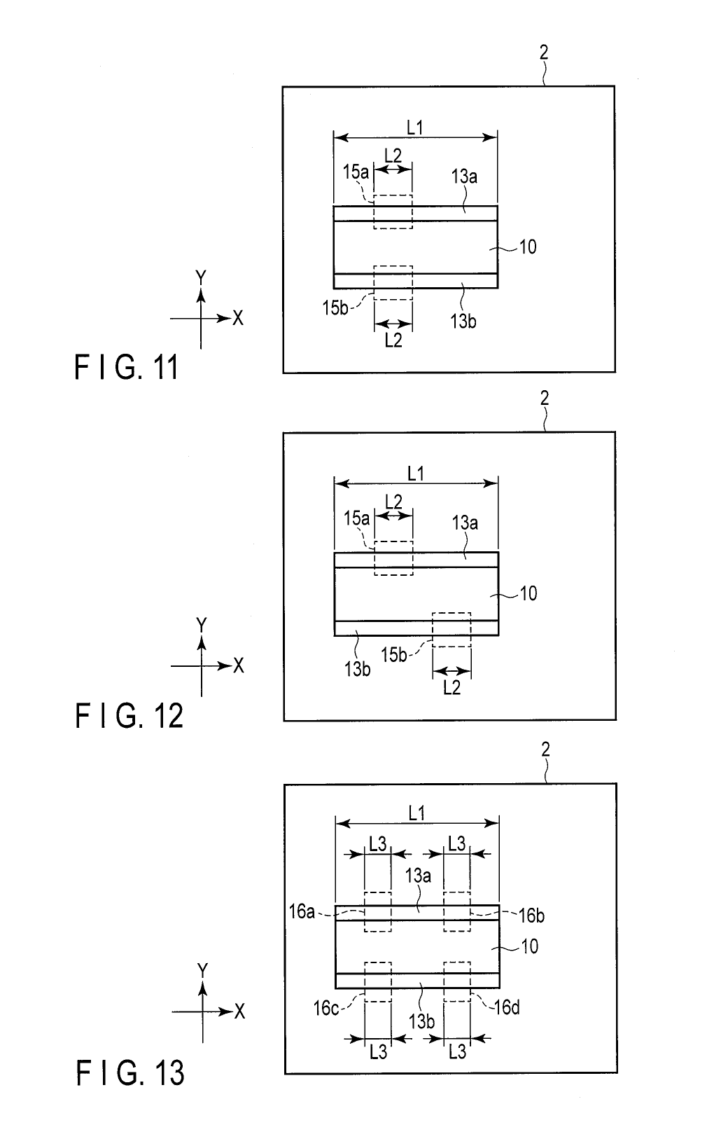

For example, as shown in FIG. 11, the pads 15a and 15b may be located at positions deviated from the central portions to one end in the external electrodes 13a and 13b . Here, if the pads 15a and 15b are located excessively close to one side of the external electrodes 13a and 13b, the other side may float when the capacitor main body 10 is bonded. Thus, it is preferable that the pads be located near the centers of the external electrodes 13a and 13b, respectively.

Alternatively, the pads 15a and 15b may not necessarily face each other, but they may be located diagonal with respect to the external electrodes 13a and 13b as shown in FIG. 12. In both cases, an advantageous effect similar to that of the above-described embodiments can be obtained by setting the width L2 of the pads 15a and 15b less than the width L1 of the external electrodes 13a and 13b.

Further, a plurality of pads may be provided for each of the external electrodes 13a and 13b. But if there are an excessive number of pads, each of the external electrodes 13a and 13b is tightly attached by its entire area to the printed circuit board 2, thus making it easy to propagate the vibration of the capacitor main body 10 to the printed circuit board 2. For this reason, the pads should preferably be provided in such a number that the pads can be arranged at as large an interval as possible for the width L1 of the external electrodes 13a and 13b.

In the Example shown in FIG. 13, two pads 16a and 16b are provided for an external electrode 13a, and two pads 16c and 16d are provided for an external electrode 13b. The width L3 of these pads is further less than the width L2 (L1>L2>L3). With this structure, in which a plurality of pads are provided on each of external electrodes 13a and 13b at an interval, an advantageous effect similar to that of the above-described embodiments can be obtained.

According to at least one of the embodiments described above, an electronic device having a capacitor mount structure can be provided, which can prevent the singing noise of the circuit board, produced as a result of the electrostrictive strain of the capacitor, without requiring a specialized component or process.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising:
a printed circuit board;
a multilayer ceramic capacitor mounted on the printed circuit board and comprising a rectangular parallelepiped capacitor main body and a pair of external electrodes with first and second pads, formed on both ends in a shorter side of the capacitor main body,
wherein portions of the pair of external electrodes are soldered to the printed circuit board while setting a width of the first and second pads provided respectively on the pair of external electrodes less than a width of the pair of external electrodes.

2. An electronic device of claim 1, wherein the first and second pads are each located in a central portion of a respective one of the pair of external electrodes on the printed circuit board.

3. An electronic device of claim 1, wherein the first and second pads are each located at a position deviated to one end of the capacitor main body from the central portion of the respective one of the pair of external electrodes on the printed circuit board.

4. An electronic device of claim 1, wherein the first and second pads are located diagonal with respect to the pair of external electrodes on the printed circuit board.

5. An electronic device of claim 1, wherein the first and second pads are each provided in a plurality at an interval with respect to the respective one of the pair of external electrodes on the printed circuit board.
